(19) United States
(12) Patent Application Publication
(10) Pub. No.: US 2019/0226090 A1
(43) Pub. Date: Jul. 25, 2019

(54) NOZZLE FOR A DISTRIBUTION ASSEMBLY OF A MATERIAL DEPOSITION SOURCE ARRANGEMENT, MATERIAL DEPOSITION SOURCE ARRANGEMENT, VACUUM DEPOSITION SYSTEM AND METHOD FOR DEPOSITING MATERIAL

(71) Applicants: Andreas LOPP, Freigerocht (DE); Dieter HAAS, San Jose, CA (US); Applied Materials, Inc., Santa Clara, CA (US)

(72) Inventors: Andreas LOPP, Freigericht-Somborn (DE); Dieter HAAS, San Jose, CA (US)

(21) Appl. No.: 15/552,022

(22) PCT Filed: Sep. 22, 2016
(86) PCT No.: PCT/EP2016/072578

§ 371 Date: Aug. 18, 2017

(51) Int. Cl. C23C 16/455

(52) U.S. Cl. CPC C23C 16/45563; C23C 14/12

(57) ABSTRACT

A nozzle for being connected to a distribution assembly for guiding evaporated material from a material source into a vacuum chamber is described. The nozzle includes: a nozzle inlet for receiving the evaporated material; a nozzle outlet for releasing the evaporated material to the vacuum chamber; and a nozzle passage extending from the nozzle inlet the nozzle outlet in a flow direction, wherein the nozzle passage comprises an outlet section having an aperture angle which continuously increases in the flow direction. Further, a material deposition arrangement having such a nozzle, a vacuum deposition system with the material source arrangement, and a method for depositing evaporated material are provided.

### TECHNICAL FIELD

Embodiments of the present disclosure relate to a nozzle for a material deposition source arrangement, a material source arrangement, a vacuum deposition system and a method for depositing material on a substrate. Embodiments of the present disclosure particularly relate to a nozzle for guiding evaporated material to a vacuum chamber of a vacuum deposition system, a material deposition source arrangement including a nozzle for guiding evaporated material to a vacuum chamber, and a method for depositing a material on a substrate in a vacuum chamber.

### BACKGROUND

Organic evaporators are a tool for the production of organic light-emitting diodes (OLED). OLEDs are a special type of light-emitting diode in which the emissive layer comprises a thin-film of certain organic compounds. Organic light emitting diodes (OLEDs) are used in the manufacture of television screens, computer monitors, mobile phones, other hand-held devices, etc., for displaying information. OLEDs can also be used for general space illumination. The range of colors, brightness, and viewing angles possible with OLED displays is greater than that of traditional LCD displays because OLED pixels directly emit light and do not use a back light. Therefore, the energy consumption of OLED displays is considerably less than that of traditional LCD displays. Further, the fact that OLEDs can be manufactured onto flexible substrates results in further applications. A typical OLED display, for example, may include layers of organic material situated between two electrodes that are all deposited on a substrate in such a manner as to form a matrix display panel having individually energizable pixels. The OLED is generally placed between two glass panels, and the edges of the glass panels are sealed to encapsulate the OLED therein.

There are many challenges encountered in the manufacture of such display devices. OLED displays or OLED lighting applications include a stack of several organic materials, which are for example evaporated in a vacuum. The organic materials are deposited in a subsequent manner through shadow masks. For the fabrication of OLED stacks with high efficiency, the co-deposition or co-evaporation of two or more materials, e.g. host and dopant, leading to mixed/doped layers is beneficial. Further, it has to be considered that there are several process conditions for the evaporation of the very sensitive organic materials.

For depositing the material on a substrate, the material is heated until the material evaporates. Pipes guide the evaporated material to the substrates through outlets or nozzles. In the past years, the precision of the deposition process has been increased, e.g. for being able to provide smaller and smaller pixel sizes. In some processes, masks are used for defining the pixels when the evaporated material passes through the mask openings. However, shadowing effects of a mask, the spread of the evaporated material and the like make it difficult to further increase the precision and the predictability of the evaporation process.

In view of the above, embodiments described herein provide a nozzle, a material deposition arrangement, a vacuum deposition system, and a method for depositing material on a substrate that overcome at least some of the problems in the art.

### SUMMARY

In light of the above, a nozzle for evaporated material, a material source arrangement, a vacuum deposition system, and a method for depositing material on a substrate according to the independent claims are provided.

According to one aspect of the present disclosure, a nozzle for being connected to a distribution assembly for guiding evaporated material from a material source into a vacuum chamber is provided. The nozzle includes: a nozzle inlet for receiving the evaporated material; a nozzle outlet for releasing the evaporated material to the vacuum chamber; and a nozzle passage extending from the nozzle inlet to the nozzle outlet in a flow direction. The nozzle passage includes an outlet section having an aperture angle α which continuously increases in the flow direction.

According to another aspect of the present disclosure, a use of a nozzle according any embodiments described herein for depositing a material on a substrate in a vacuum deposition chamber is provided, particularly for producing an organic light emitting diode.

According to a further aspect of the present disclosure, a material deposition source arrangement for depositing a material on a substrate in a vacuum deposition chamber is provided. The material deposition source arrangement includes a distribution assembly being configured to be in fluid communication with a material source providing the material to the distribution assembly, and at least one nozzle according to any embodiments described herein.

According to a further aspect of the present disclosure, a vacuum deposition system is provided. The vacuum deposition includes: a vacuum deposition chamber; a material deposition source arrangement according to any embodiments described herein in the vacuum chamber; and a substrate support for supporting the substrate during deposition.

According to another aspect of the present disclosure, a method for depositing a material on a substrate in a vacuum deposition chamber is provided. The method includes: evaporating a material to be deposited in a crucible; providing the evaporated material to a distribution assembly being in fluid communication with the crucible; and guiding the evaporated material through a nozzle having a nozzle passage extending from a nozzle inlet to a nozzle outlet in a flow direction to the vacuum deposition chamber, wherein guiding the evaporated material through the nozzle comprises guiding the evaporated material through an outlet section of the nozzle passage having an aperture angle α which continuously increases in the flow direction up to angle of α≥40° relative to the flow direction.

Further advantages, features, aspects and details are apparent from the dependent claims, the description and drawings.

### BRIEF DESCRIPTION OF THE DRAWINGS

So that the manner in which the above recited features of the present disclosure can be understood in detail, a more particular description of the present disclosure, briefly summarized above, may be had by reference to embodiments. The accompanying drawings relate to embodiments of the disclosure and are described in the following. Embodiments are depicted in the drawings and are detailed in the description which follows.

FIG. 1 shows a schematic cross-sectional view of a nozzle according to embodiments described herein for being connected to a distribution assembly for guiding evaporated material from a material source into a vacuum chamber;

FIGS. 2 and 3 show schematic cross-sectional views of a nozzle according to further embodiments described herein;

FIG. 4 shows a schematic cross-sectional view of a nozzle according to embodiments described herein, wherein a typical flow profile of the evaporated material which has been guided through a nozzle according to embodiments described herein is illustrated;

FIG. 5A shows a schematic side view of a material deposition source arrangement according to embodiments described herein;

FIG. 5B shows a section of the schematic view of the material deposition source arrangement of FIG. 5A in more detail;

FIG. 6 shows a schematic side view of a material deposition source arrangement according to further embodiments described herein;

FIG. 7 shows a vacuum deposition system according to embodiments described herein;

FIGS. 8A and 8B show schematic views of a distribution assembly having nozzles according to embodiments described herein; and

FIG. 9 shows a flow chart of a method for depositing material on a substrate according to embodiments described herein.

### DETAILED DESCRIPTION OF EMBODIMENTS

Reference will now be made in detail to the various embodiments, one or more examples of which are illustrated in each figure. Each example is provided by way of explanation and is not meant as a limitation. For example, features illustrated or described as part of one embodiment can be used on or in conjunction with any other embodiment to yield yet a further embodiment. It is intended that the present disclosure includes such modifications and variations.

Within the following description of the drawings, the same reference numbers refer to the same or to similar components. Generally, only the differences with respect to the individual embodiments are described. Unless specified otherwise, the description of a part or aspect in one embodiment applies to a corresponding part or aspect in another embodiment as well.

Before various embodiments of the present disclosure are described in more detail, some aspects with respect to some terms used herein are explained.

As used herein, the term “fluid communication” may be understood in that two elements being in fluid communication can exchange fluid via a connection, allowing fluid to flow between the two elements. In one example, the elements being in fluid communication may include a hollow structure, through which the fluid may flow. According to some embodiments, at least one of the elements being in fluid communication may be a pipe-like element.

In the present disclosure, a “material deposition arrangement” or “material deposition source arrangement” (both terms may be used synonymously herein) may be understood as an arrangement providing a material to be deposited on a substrate.

In particular, the material deposition source arrangement may be configured for providing material to be deposited on a substrate in a vacuum chamber, such as a vacuum deposition chamber of a vacuum deposition system. According to some embodiments, the material deposition source arrangement may provide the material to be deposited on the substrate by being configured to evaporate the material to be deposited. For instance, the material deposition arrangement may include an evaporator or a crucible, which evaporates the material to be deposited on the substrate, and a distribution assembly, e.g. a distribution pipe or one or more point sources which can be arranged along a vertical axis. The distribution assembly is configured to release the evaporated material in a direction towards the substrate, e.g. through an outlet or a nozzle as described herein. A crucible may be understood as a device or a reservoir providing or containing the material to be deposited. Typically, the crucible may be heated for evaporating the material to be deposited on the substrate. The crucible may stand in fluid communication with a distribution assembly, to which the material being evaporated by the crucible may be delivered. In one example, the crucible may be a crucible for evaporating organic materials, e.g. organic materials having an evaporation temperature of about 100° C. to about 600° C.

According to some embodiments described herein, a “distribution assembly” may be understood as a distribution pipe for guiding and distributing the evaporated material. In particular, the distribution pipe may guide the evaporated material from an evaporator to an outlet (such as nozzles or openings) in the distribution pipe. For instance, the distribution pipe can be a linear distribution pipe extending in a first, especially longitudinal, direction. In some embodiments, the linear distribution pipe includes a pipe having the shape of a cylinder, wherein the cylinder may have a circular, a triangular or square-like bottom shape or any other suitable bottom shape.

In the present disclosure, a “nozzle” as referred to herein may be understood as a device for guiding a fluid, especially for controlling the direction or characteristics of a fluid (such as the rate of flow, speed, shape, and/or the pressure of the fluid that emerges from the nozzle). According to some embodiments described herein, a nozzle may be a device for guiding or directing a vapor, such as a vapor of an evaporated material to be deposited on a substrate. The nozzle may have an inlet for receiving a fluid, a passage (e.g. a bore or opening) for guiding the fluid through the nozzle, and an outlet for releasing the fluid. Typically, the passage may include a passage wall surrounding a passage channel, through which the evaporated material may flow. According to embodiments described herein, the passage of the nozzle may include a defined geometry for achieving the direction or characteristic of the fluid flowing through the nozzle. According to some embodiments, a nozzle may be part of a distribution assembly, e.g. a distribution pipe or one or more point sources which can be arranged along a vertical axis. Additionally or alternatively, a nozzle as described herein may be connectable or connected to the distribution assembly providing evaporated material and may receive evaporated material from the distribution assembly. Typically, a nozzle according to embodiments described herein may be used to focus evaporated material in the gaseous phase from an evaporator source to a substrate within a vacuum chamber, e.g. for generating an OLED active layer on a substrate.

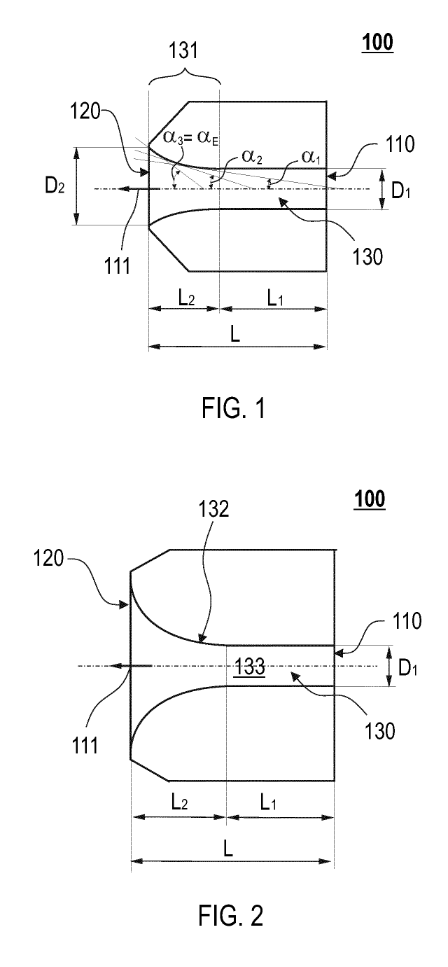

FIGS. 1 to 4 show examples of a nozzle 100 according to embodiments described herein for being connected to a distribution assembly for guiding evaporated material from a material source into a vacuum chamber. All exemplary embodiments of the nozzle 100 show a nozzle inlet 110, a nozzle outlet 120, and a nozzle passage 130 between the nozzle inlet 110 and the nozzle outlet 120. According to some embodiments, the evaporated material coming from the material source (such as a crucible) is guided into a distribution assembly as described herein and enters the nozzle through the nozzle inlet 110. The evaporated material then passes through the nozzle passage 130 and exits the nozzle at the nozzle outlet 120. The flow direction 111 of the evaporated material can be described as running from the nozzle inlet 110 to the nozzle outlet 120. The nozzle 100 further provides a length direction running along the length L of the nozzle. With exemplary reference to FIG. 1, according to embodiments of the nozzle as described herein, the nozzle passage 130 comprises an outlet section 131 having an aperture angle α which continuously increases in the flow direction 111.

Accordingly, by employing a nozzle according to embodiments described herein for depositing evaporated material onto a substrate, a shadowing effect due to a mask provided in front of the substrate can be reduced, which is described in more detail with reference to FIG. 4 in the following.

According to embodiments described herein, the nozzle passage 130 includes a passage wall 132 surrounding a passage channel 133 (shown in FIG. 2 only for the sake of a better overview). The passage wall 132 surrounding the passage channel 133 may be understood in that the passage wall surround the passage channel over the circumference of the passage channel. Accordingly, the passage wall leaves the passage channel open at two ends, i.e. the nozzle inlet 110 and the nozzle outlet 120.

According to embodiments, which can be combined with other embodiments described herein, the outlet section 131 of the nozzle passage 130 is configured to have an aperture angle α which continuously increases in the flow direction 111 up to an angle of α≥50° relative to the flow direction 111. For instance, the outlet section 131 may have a length (e.g. a second length L2 as described in more detail in the following) along which aperture angle α continuously increases up to the nozzle outlet 120. A continuous increase of the aperture angle α is exemplarily illustrated in FIG. 1, in which the aperture angle α is shown at three different positions of the outlet section 131, e.g. α₁<α₂<α₃ In particular, starting from a first end of the outlet section 131 arranged within the nozzle passage 130, the aperture angle α continuously increases up to a second end of the outlet section which includes the nozzle outlet 120. For example, the aperture angle α at the nozzle outlet may be referred to as exit aperture angle α_{E} which can be α_{E}≥40°, particularly α_{E}≥50°, more particularly α_{E}≥60°.

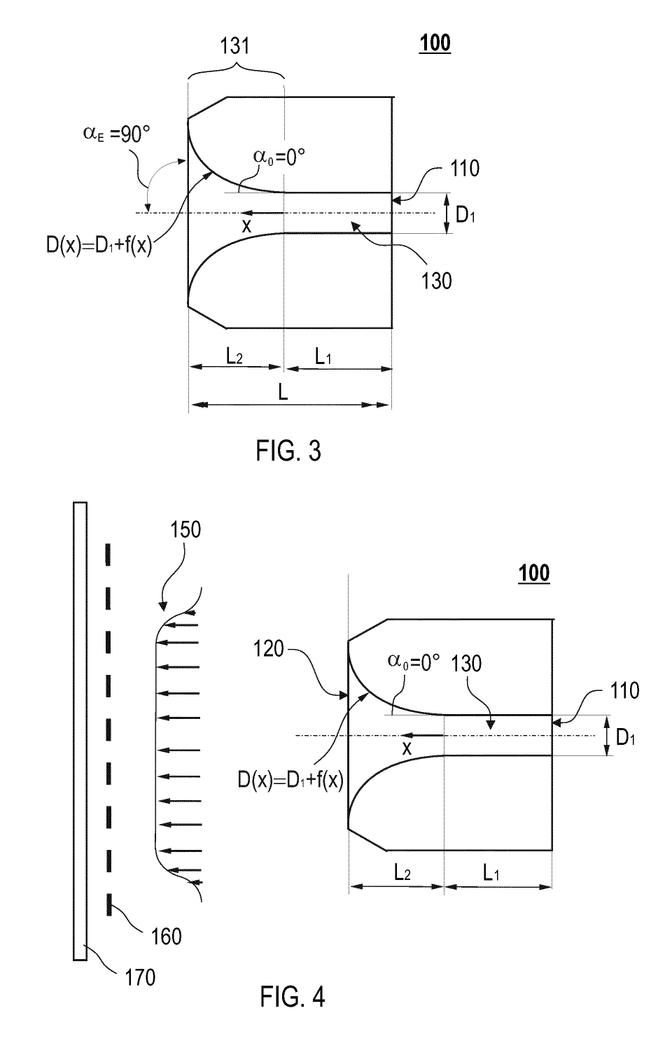

With exemplary reference to FIG. 3, according to embodiments which can be combined with other embodiments described herein, the aperture angle α of the outlet section 131 of the nozzle passage 130 may continuously increase in the flow direction from an angle of α=0° relative to the flow direction 111 up to an angle of α=90° at the nozzle outlet 120, i.e. an exit aperture angle α_{E}=90°, relative to the flow direction 111. An angle of exit aperture angle α_{E}=90° at the nozzle outlet 120 relative to the flow direction 111 can be beneficial for a homogeneous flow profile over a large distance from the nozzle outlet 120, as exemplarily described in more detail with reference to FIG. 4.

According to embodiments, which can be combined with other embodiments described herein, the aperture angle α of the outlet section 131 may continuously increase in an exponential manner in the flow direction 111. In particular, as exemplarily illustrated in FIG. 3, the aperture angle α of the outlet section 131 may continuously increase in the flow direction such that the diameter of the outlet section increases as a function of an x-coordinate which corresponds to the main flow direction. Accordingly, the increase of the diameter of the outlet section 131 can be described as D=f(x). In particular, the x-coordinate may start from a first end of the outlet section 131 arranged within the nozzle passage 130 at a position at which the aperture angle α changes from α=0° to a positive value of the aperture angle α, e.g. α=0°+Δα. Accordingly, a continuous increase of the diameter of the outlet section 131 can be described as D(x)=D₁+(b^{x}−1), wherein b is a constant value >1, and D₁ is the inlet diameter at the nozzle inlet 110.

According to embodiments, which can be combined with other embodiments described herein, the diameter of the outlet section 131 may continuously increase according to the function D(x)=D₁+a·x², wherein a is a constant value which can be selected from a range of 0.05≤a≤2, particularly 0.1≤a≤1, more particularly 0.2≤a≤0.7, for instance a=0.5.

According to some embodiments, which can be combined with other embodiments described herein, the aperture angle (α) may continuously increase in the flow direction such that such that the diameter of the outlet section 131 of the nozzle passage 130 continuously increases in a circular-segment-like manner in the flow direction. According to some embodiments, which can be combined with other embodiments described herein, the aperture angle (α) continuously increases in the flow direction such that the diameter of the outlet section 131 of the nozzle passage 130 or the aperture angle α of the outlet section 131 of the nozzle passage 130 continuously increases in a parabola-like manner in the flow direction.

Accordingly, by employing a nozzle according to embodiments described herein for depositing evaporated material onto a substrate, a homogeneous flow profile over a large distance from the nozzle outlet can be provided such that for example a shadowing effect due to a mask provided in front of the substrate can be reduced, which is described in more detail with reference to FIG. 4 in the following.

According to typical embodiments, which can be combined with other embodiments described herein, the nozzle is configured for guiding an evaporated organic material having a temperature between about 100° C. and about 600° C. to the vacuum chamber. Further, the nozzle can be configured for a mass flow of less than 0.5 sccm. For instance, the mass flow within a nozzle according to embodiments described herein may particularly be only a fractional amount of 0.5 sccm, and more particularly below 0.25 sccm. In one example, the mass flow in a nozzle according to embodiments described herein may be less than 0.1 sccm, such as less than 0.05, particularly less than 0.03 sccm, more particularly less than 0.02 sccm

Additionally or alternatively, the nozzle passage has a minimum dimension of less than 8 mm, particularly less than 5 mm. In particular, with exemplary reference to FIG. 2, the minimum dimension of the nozzle passage 130 may be the inlet diameter D₁ at the nozzle inlet 110. As exemplarily shown in FIG. 2, the inlet diameter D₁ may be constant over a first length L1 of a first section of the nozzle passage 130. For instance, the inlet diameter D₁ may be D₁≤8 mm, particularly D₁≤5 mm.

According to embodiments, which can be combined with other embodiments described herein, the nozzle may include a nozzle passage having sections of different length. For instance, FIG. 1 shows a nozzle 100 with a first passage section having a first length L1 and a second passage section having a second length L2. In particular, a length of a nozzle section is to be understood as the dimension of nozzle section along the length direction of the nozzle, or along the main flow direction, i.e. the flow direction 111 exemplarily shown in FIG. 1, of the evaporated material in the nozzle. The first passage section of the nozzle provides a first diameter, e.g. the inlet diameter D₁. The second passage section of the nozzle provides a continuously increasing diameter, which continuously increases from the first diameter to a second diameter, e.g. the outlet diameter D₂. In other words, according to some embodiments, which may be combined with other embodiments described herein, the first passage section of the nozzle may include the nozzle inlet and the second passage section of the nozzle may include the nozzle outlet. In particular, the second passage section may be the outlet section of the nozzle passage as described herein.

According to some embodiments, which can be combined with other embodiments described herein, the second diameter may be between 1.5 to 10 times larger than the first diameter, more particularly between 1.5 and 8 times larger, and even more particularly between 2 and 6 times larger. In one example, the second diameter may be 4 times larger than the first diameter. Additionally or alternatively, the first diameter (i.e. the inlet diameter D₁), may be between 1.5 mm and about 8 mm, more particularly between about 2 mm and about 6 mm, and even more particularly between about 2 mm and about 4 mm. According to some embodiments, the second diameter (i.e. the outlet diameter D₂) may be between 3 mm and about 20 mm, more particularly between about 4 mm and about 15 mm, and even more particularly between about 4 mm and about 10 mm.

According to some embodiments, which may be combined with other embodiments described herein, the first length L1 of first passage section and/or the second length L2 of the second passage section may be between 2 mm and about 20 mm, more particularly between about 2 mm and about 15 mm, and even more particularly between about 2 mm and about 10 mm. In one example, first length L1 of first passage section and/or the second length L2 of the second passage section may be about 5 mm to about 10 mm.

Accordingly, embodiments of the nozzle as described herein are configured to provide an increasing conductance value with increasing distance from the nozzle inlet to the nozzle outlet. In particular, by providing a nozzle with an outlet section as described herein, the conductance increases in the flow direction to the nozzle outlet. More particularly, the outlet section of the nozzle as described herein provides for a continuously increasing conductance value in the flow direction to the nozzle outlet. For instance, the conductance value may be measured in l/s. In one example, the flow within the nozzle being below 1 sccm may also be described as being below 1/60 mbar l/s. Further, a nozzle with an outlet section as described herein provides for a continuously decreasing pressure level in the outlet section in the flow direction to the nozzle outlet.

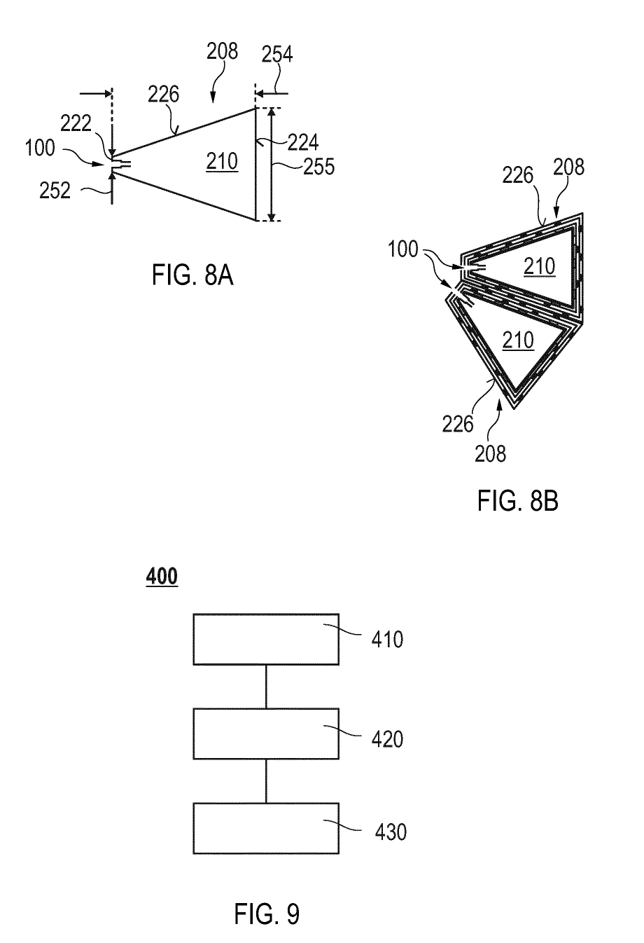

According to some embodiments, the first passage section may be configured to increase the uniformity of the evaporated material guided from the distribution assembly, e.g. a distribution pipe into the nozzle, especially by having a smaller diameter than the second passage section, or by having a smaller diameter when compared to the diameter of the distribution assembly, particularly the distribution pipe. According to some embodiments, the diameter of the distribution pipe, (to which the nozzle may be connected, or of which the nozzle may be a part of) may be between about 70 mm and about 120 mm, more particularly between about 80 mm and about 120 mm, and even more particularly between about 90 mm and about 100 mm. In some embodiments described herein (e.g. in the case of a distribution pipe having a substantially triangular like shape as explained in detail below with respect to FIGS. 8A and 8B), the above described values for the diameter may refer to the hydraulic diameter of the distribution pipe. According to some embodiments, the comparatively narrow first passage section may force the particles of the evaporated material to arrange in a more uniform manner. Making the evaporated material more uniform in the first passage section may for instance include making the density of the evaporated material, the velocity of the single particles and/or the pressure of the evaporated material more uniform. A more uniform flow results in less spreading particles and a smaller spreading angle.

The skilled person may understand that in a material deposition arrangement according to embodiments described herein, such as a material deposition arrangement for evaporating organic materials, the evaporated material flowing in the distribution pipe and the nozzle (or parts of the nozzle) may be considered as a Knudsen flow. In particular, the evaporated material may be considered as a Knudsen flow in view of the flow and pressure conditions in the distribution pipe and the nozzle for guiding evaporated material in a vacuum chamber, which will be explained in detail below. According to some embodiments described herein, the flow in a portion of the nozzle (such as the outlet section including the nozzle outlet) may be a molecular flow. For instance, the outlet section of the nozzle according to embodiments described herein may provide a transition between a Knudsen flow and a molecular flow. In one example, the flow within the vacuum chamber, but outside of the nozzle, may be a molecular flow. According to some embodiments, the flow in the distribution pipe may be considered as being a viscous flow or a Knudsen flow. In some embodiments, the nozzle may be described as providing a transition from the Knudsen flow or viscous flow to the molecular flow.

With exemplary reference to FIG. 4, an exemplary flow profile 150 of evaporated material provided through a nozzle as described herein is shown. In particular, embodiments of the nozzle as described herein provides for a homogeneous flow profile over a large distance from the nozzle outlet 120. In other words, the nozzle as described herein provides for a flow profile in which the velocity vectors of the flow of evaporated material is substantially unidirectional and substantially constant at a position at which a mask 160 is provided in front of a substrate 170. The term “substantially” as used herein may mean that there may be a certain deviation from the characteristic denoted with “substantially.” Typically, a deviation of about 15% of the dimensions or the shape of the characteristic denoted with “substantially” may be possible. Accordingly, by employing a nozzle according to embodiments described herein for depositing evaporated material onto a substrate, a shadowing effect due to the mask provided in front of the substrate can be reduced.

For example, if masks are used for depositing material on a substrate, such as in an OLED production system, the mask may be a pixel mask with pixel openings having the size of about 50 μm×50 μm, or even below, such as a pixel opening with a dimension of the cross section (e.g. the minimum dimension of a cross section) of about 30 μm or less, or about 20 μm. In one example, the pixel mask may have a thickness of about 40 μm. Considering the thickness of the mask and the size of the pixel openings, a shadowing effect may appear, where the walls of the pixel openings in the mask shadow the pixel opening. The nozzle according to embodiments described herein may help in reducing the shadowing effect such that displays with a high pixel density (dpi), particularly Ultra High Definition (UHD) displays (e.g. UHD-OLED displays), can be produced.

Further, the high directionality which can be achieved by using a nozzle according to embodiments described herein results in an improved utilization of the evaporated material, because more of the evaporated material actually reaches the substrate.

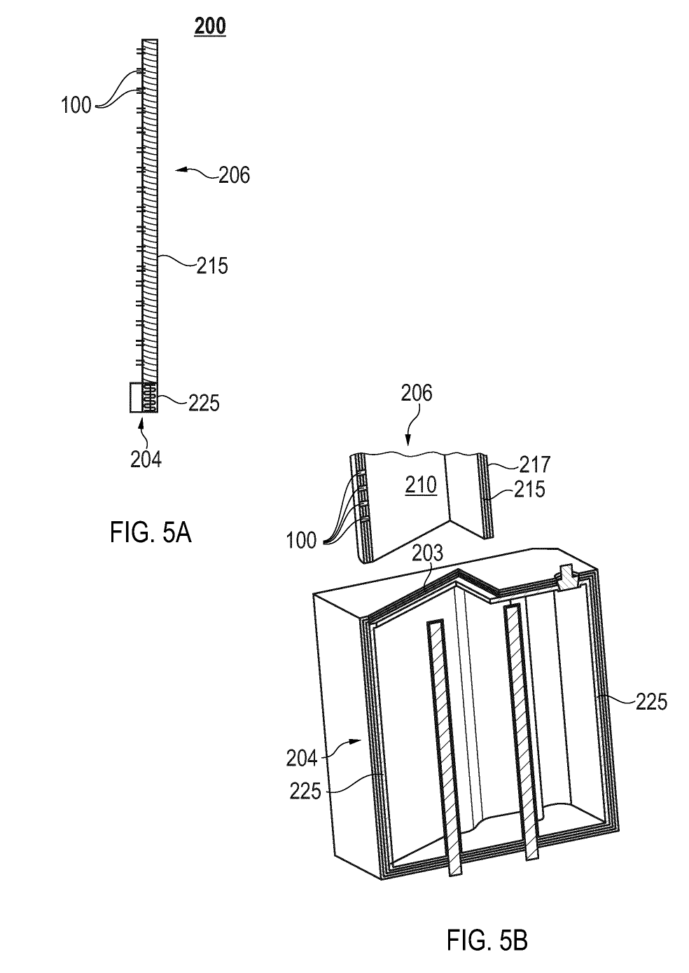

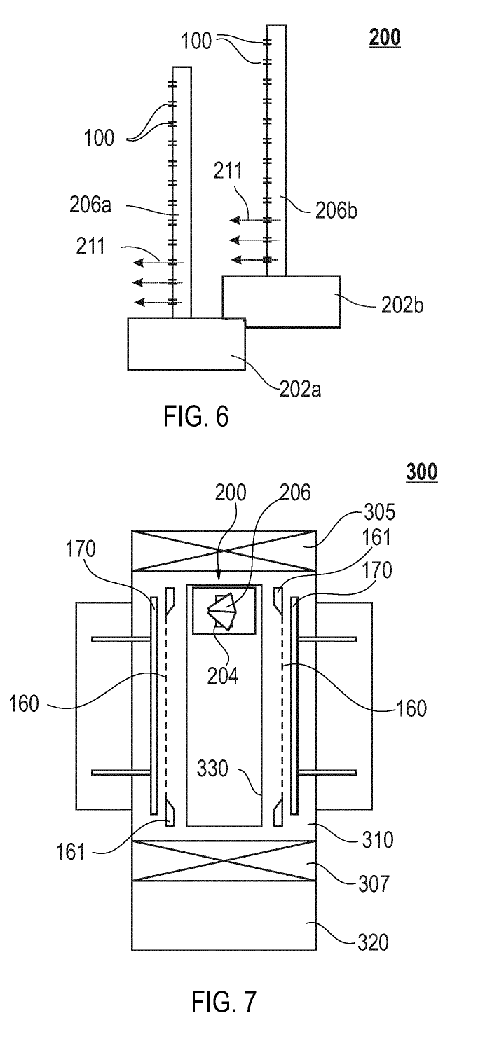

With exemplary reference to FIGS. 5A, 5B and 6, a material deposition source arrangement 200 for depositing a material on a substrate in a vacuum deposition chamber is described. The material deposition source arrangement 200 typically includes a distribution assembly 206, e.g. a distribution pipe, configured to be in fluid communication with a material source 204 (e.g. an evaporator or a crucible) providing the material to the distribution assembly. The material deposition source arrangement further includes at least one nozzle according to embodiments described above, e.g. with respect to FIGS. 1 to 4.

As exemplarily shown in FIGS. 5A and 5B, the distribution assembly 206 of the material deposition source arrangement 200 may be configured as a distribution pipe. The distribution pipe may stand in fluid communication with the material source 204, e.g. a crucible, and be configured for distributing evaporated material provided by the material source 204. The distribution pipe can for example be an elongated cube with heating unit 215. The evaporation crucible can be a reservoir for the organic material to be evaporated with a source heating unit 225. According to typical embodiments, which can be combined with other embodiments described herein, the distribution pipe may provide a line source. According to some embodiments described herein, the material deposition arrangement further includes a plurality of nozzles according to embodiments described herein for releasing the evaporated material towards the substrate.

According to some embodiments, which can be combined with other embodiments described herein, the nozzles of the distribution pipe may be adapted for releasing the evaporated material in a direction different from the length direction of the distribution pipe, such as a direction being substantially perpendicular to the length direction of the distribution pipe. According to some embodiments, the nozzles are arranged to have a main evaporation direction (also referred to as flow direction 111 in FIGS. 1 to 4) being horizontal +−20°. According to some specific embodiments, the evaporation direction can be oriented slightly upward, e.g. to be in a range from horizontal to 15° upward, such as 3° to 7° upward. Correspondingly, the substrate can be slightly inclined to be substantially perpendicular to the evaporation direction. Undesired particle generation can be reduced. However, the nozzle and the material deposition arrangement according to embodiments described herein may also be used in a vacuum deposition system, which is configured for depositing material on a horizontally oriented substrate.

In one example, the length of the distribution pipe corresponds at least to the height of the substrate to be deposited in the deposition system. In many cases, the length of the distribution pipe will be longer than the height of the substrate to be deposited, at least by 10% or even 20%. A uniform deposition at the upper end of the substrate and/or the lower end of the substrate can be provided.

According to some embodiments, which can be combined with other embodiments described herein, the length of the distribution pipe can be 1.3 m or above, for example 2.5 m or above. According to one configuration, as shown in FIG. 5A, the material source 204, particularly the evaporation crucible, is provided at the lower end of the distribution pipe. The organic material is evaporated in the evaporation crucible. The vapor of organic material enters the distribution pipe at the bottom of the distribution pipe and is guided essentially sideways through the plurality of nozzles in the distribution pipe, e.g. towards an essentially vertical substrate.

FIG. 5B shows an enlarged schematic view of a portion of the material deposition arrangement, wherein the distribution assembly 206, particularly the distribution pipe, is connected to the material source 204, particularly the evaporation crucible. A flange unit 203 is provided, which is configured to provide a connection between the evaporation crucible and the distribution pipe. For example, the evaporation crucible and the distribution pipe are provided as separate units, which can be separated and connected or assembled at the flange unit, e.g. for operation of the material deposition arrangement.

The distribution assembly 206 has an inner hollow space 210. A heating unit 215 may be provided to heat the distribution assembly, particularly the distribution pipe. Accordingly, the distribution assembly can be heated to a temperature such that the vapor of the organic material, which is provided by the evaporation crucible, does not condense at an inner portion of the wall of the distribution assembly. For instance, the distribution assembly, particularly the distribution pipe, may be held at a temperature which is typically about 1° C. to about 20° C., more typically about 5° C. to about 20° C., and even more typically about 10° C. to about 15° C. higher than the evaporation temperature of the material to be deposited on the substrate. Further, two or more heat shields 217 may be provided around the distribution assembly, particularly around the tube of the distribution pipe.

For instance, during operation, the distribution assembly 206 (e.g. the distribution pipe) may be connected to the material source 204 (e.g. the evaporation crucible) at the flange unit 203. Typically, the material source, e.g. the evaporation crucible, is configured to receive the organic material to be evaporated and to evaporate the organic material. According to some embodiments, the material to be evaporated may include at least one of ITO, NPD, Alq3, Quinacridone, Mg/AG, starburst materials, and the like.

In one example, the pressure in the distribution assembly, particularly the distribution pipe, may be between about 10⁻² mbar to about 10⁻⁵ mbar, or between about 10⁻² to about 10-³ mbar. According to some embodiments, the vacuum chamber may provide a pressure of about 10⁻⁵ to about 10⁻⁷ mbar.

As described herein, the distribution assembly can be a distribution pipe having a hollow cylinder. The term cylinder can be understood as having a circular bottom shape, a circular upper shape and a curved surface area or shell connecting the upper circle and the small lower circle. According to further additional or alternative embodiments, which can be combined with other embodiments described herein, the term cylinder can further be understood in the mathematical sense as having an arbitrary bottom shape, an identical upper shape and a curved surface area or shell connecting the upper shape and the lower shape. Accordingly, the cylinder does not necessarily need to have a circular cross-section. Instead, the base surface and the upper surface can have a shape different from a circle.

FIG. 6 shows a schematic side view of a material deposition source arrangement 200 according to further embodiments described herein. The material deposition source arrangement includes two evaporators 202a and 202b, and two distribution pipes 206a and 206b standing in fluid communication with the respective evaporators. The material deposition arrangement further includes nozzles 100 in the distribution pipes 206a and 206b. The nozzles 100 may be nozzles as described above with respect to FIGS. 1 to 4. According to some embodiments, the nozzles may have a distance between each other. For instance, the distance between the nozzles may be measured as the distance between the longitudinal axis 211 of the nozzles. According to some embodiments, which may be combined with other embodiments described herein, the distance between the nozzles may typically be between about 10 mm and about 50 mm, more typically between about 10 mm and about 40 mm, and even more typically between about 10 mm and about 30 mm.

In particular, the above described distances between the nozzles may be beneficial for the deposition of organic materials through a pixel mask, such as a mask having an opening size of 50 μm×50 μm, or even less, such as a pixel opening with a dimension of the cross section (e.g. the minimum dimension of a cross section) of about 30 μm or less, or about 20 μm.

With exemplary reference to FIG. 7, exemplary embodiments of a vacuum deposition system 300 are described. According to embodiments, which can be combined with any other embodiments described herein, the vacuum deposition system 300 includes a vacuum deposition chamber 310 and a material deposition source arrangement 200 as exemplarily described above with reference to FIGS. 5A, 5B and 6. The vacuum deposition system further includes a substrate support for supporting the substrate during deposition.

In particular, FIG. 7 shows a vacuum deposition system 300 in which a nozzle 100 and a material deposition source arrangement 200 according to embodiments described herein may be used. The vacuum deposition system 300 includes a material deposition source arrangement 200 (or material deposition arrangement) in a position in a vacuum deposition chamber 310. The material deposition source arrangement 200 may be configured for a translational movement and a rotation around an axis, particularly a vertical axis. The material deposition arrangement 200 has one or more material sources 204, particularly one or more evaporation crucibles, and one or more distribution assemblies, particularly one or more distribution pipes. For instance, in FIG. 9, two evaporation crucibles and two distribution pipes are shown. Further, two substrates 170 are provided in the vacuum deposition chamber 310. Typically, a mask 160 for masking of the layer deposition on the substrate can be provided between the substrate and the material deposition source arrangement 200.

According to embodiments described herein, the substrates are coated with organic material in an essentially vertical position. The view shown in FIG. 7 is a top view of a system including the material deposition source arrangement 200. Typically, the distribution assembly is configured to be a distribution pipe having a vapor distribution showerhead, particularly a linear vapor distribution showerhead. The distribution pipe provides a line source extending essentially vertically. According to embodiments described herein, which can be combined with other embodiments described herein, essentially vertically is understood particularly when referring to the substrate orientation, to allow for a deviation from the vertical direction of 20° or below, e.g. of 10° or below. The deviation can be provided for example because a substrate support with some deviation from the vertical orientation might result in a more stable substrate position. The surface of the substrates is typically coated by a line source extending in one direction corresponding to one substrate dimension, e.g. the vertical substrate dimension, and a translational movement along the other direction corresponding to the other substrate dimension, e.g. the horizontal substrate dimension. According to other embodiments, the deposition system may be a deposition system for depositing material on an essentially horizontally oriented substrate. For instance, coating of a substrate in a deposition system may be performed in an up or down direction.

With exemplary reference to FIG. 7, the material deposition source arrangement 200 may be configured to be movable within the vacuum deposition chamber 310, such as by a rotational or a translational movement. For instance, the material source shown in the example of FIG. 7 is arranged on a track 330, e.g. a looped track or linear guide. Typically, the track or the linear guide is configured for the translational movement of the material deposition arrangement. According to different embodiments, which can be combined with other embodiments described herein, a drive for the translational or rotational movement can be provided in the material deposition arrangement within the vacuum chamber or a combination thereof. Further, in the exemplary embodiment of FIG. 7, a valve 305, for example a gate valve, is shown. The valve 305 may allow for a vacuum seal to an adjacent vacuum chamber (not shown in FIG. 7). The valve can be opened for transport of a substrate 170 or a mask 160 into the vacuum deposition chamber 310 or out of the vacuum deposition chamber 310.

According to some embodiments, which can be combined with other embodiments described herein, a further vacuum chamber, such as a maintenance vacuum chamber 320 can be provided adjacent to the vacuum deposition chamber 310. Typically, the vacuum deposition chamber 310 and the maintenance vacuum chamber 320 are connected with a further valve 307. The further valve 307 is configured for opening and closing a vacuum seal between the vacuum deposition chamber 310 and the maintenance vacuum chamber 320. The material deposition source arrangement 200 can be transferred to the maintenance vacuum chamber 320 while the further valve 307 is in an open state. Thereafter, the valve can be closed to provide a vacuum seal between the vacuum deposition chamber 310 and the maintenance vacuum chamber 320. If the further valve 307 is closed, the maintenance vacuum chamber 320 can be vented and opened for maintenance of the material deposition arrangement without breaking the vacuum in the vacuum deposition chamber 310.

As exemplarily shown in FIG. 7, according to embodiments which can be combined with any other embodiment described herein, two substrates 170 can be supported on respective transportation tracks within the vacuum chamber. Further, two tracks for providing masks 160 thereon can be provided. Accordingly, during coating the substrates can be masked by respective masks. According to typical embodiments, the masks 160, i.e. a first mask corresponding to a first substrate and a second mask corresponding to a second substrate, are provided in a mask frame 161 to hold the mask 160 in a predetermined position. For instance, the first mask and the second mask may be pixel masks.

It is to be understood that the described material deposition source arrangement and the vacuum deposition system may be used for various applications, including applications for OLED device manufacturing including processing methods, wherein two or more organic materials are evaporated simultaneously. Accordingly, as for example shown in FIG. 7, two or more distribution pipes and corresponding evaporation crucibles can be provided next to each other. Although the embodiment shown in FIG. 7 provides a deposition system with a movable source, the skilled person may understand that the above described embodiments may also be applied in deposition systems in which the substrate is moved during processing. For instance, the substrates to be coated may be guided and driven along stationary material deposition arrangements.

According to some embodiments, which can be combined with any other embodiment described herein, the vacuum deposition system is configured for large area substrates or substrate carriers supporting one or more substrates. For instance, the large area substrate may be used for display manufacturing and may be a glass or plastic substrate. In particular, substrates as described herein shall embrace substrates which are typically used for an LCD (Liquid Crystal Display), a PDP (Plasma Display Panel), an OLED display and the like. For example, a “large area substrate” can have a main surface with an area of 0.5 m² or larger, particularly of 1 m² or larger. In some embodiments, a large area substrate can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

The term “substrate” as used herein shall particularly embrace inflexible substrates, e.g., glass plates and metal plates. However, the present disclosure is not limited thereto and the term “substrate” can also embrace flexible substrates such as a web or a foil. According to some embodiments, the substrate can be made from any material suitable for material deposition. For instance, the substrate can be made of a material selected from the group consisting of glass (for instance soda-lime glass, borosilicate glass etc.), metal, polymer, ceramic, compound materials, carbon fiber materials, mica or any other material or combination of materials which can be coated by a deposition process. For example, the substrate can have a thickness of 0.1 mm to 1.8 mm, such as 0.7 mm, 0.5 mm or 0.3 mm. In some implementations, the thickness of the substrate may be 50 μm or more and/or 700 μm or less. Handling of thin substrates with a thickness of only a few microns, e.g. 8 μm or more and 50 μm or less, may be challenging.

According to some embodiments, which may be combined with other embodiments described herein, a material source, an evaporator or a crucible as described herein may be configured to receive organic material to be evaporated and to evaporate the organic material. According to some embodiments, the material to be evaporated may include at least one of ITO, NPD, Alq3, Quinacridone, Mg/AG, starburst materials, and the like. Typically, as described herein, the nozzle may be configured for guiding evaporated organic material to the vacuum chamber. For instance, the material of the nozzle may be adapted for evaporated organic material having a temperature of about 100° C. to about 600° C. For instance, in some embodiments, the nozzle may include a material having a thermal conductivity larger than 21 W/mK and/or a material being chemically inert to evaporated organic material. According to some embodiments, the nozzle may include at least one of Cu, Ta, Ti, Nb, DLC, and graphite or may include a coating of the passage wall with one of the named materials.

With exemplary reference to FIG. 8A, according to some embodiments which may be combined with other embodiments described herein, the distribution pipe of the material deposition source arrangement may have a substantially triangular cross-section. The distribution pipe 208 has walls 222, 226, and 224, which surround an inner hollow space 210. The wall 222 is provided at an outlet side of the distribution pipe, at which a nozzle 100 or several nozzles are provided. The nozzles may be nozzles as described with respect to FIGS. 1 to 4. Further, and not limited to the embodiment shown in FIG. 8A, the nozzle may be connectable (such as screwable) to the distribution pipe or may be integrally formed in the distribution pipe. The cross-section of the distribution pipe can be described as being essentially triangular. A triangular shape of the distribution pipe makes it possible to bring the outlets, e.g. nozzles, of neighboring distribution pipes as close as possible to each other. This allows for achieving an improved mixture of different materials from different distribution pipes, e.g. for the case of the co-evaporation of two, three or even more different materials.

The width of the outlet side of the distribution pipe, e.g. the dimension of the wall 222 in the cross-section shown in FIG. 8A, is indicated by arrow 252. Further, the other dimensions of the cross-section of the distribution pipe 208 are indicated by arrows 254 and 255. According to embodiments described herein, the width of the outlet side of the distribution pipe is 30% or less of the maximum dimension of the cross-section, e.g. 30% of the larger dimension of the dimensions indicated by arrows 254 and 255. In light of the dimensions and the shape of the distribution pipe, the nozzles 100 of neighboring distribution pipes can be provided at a smaller distance. The smaller distance improves mixing of organic materials, which are evaporated next to each other.

FIG. 8B shows an embodiment in which two distribution pipes are provided next to each other. Accordingly, a material deposition arrangement having two distribution pipes as shown in FIG. 8B can evaporate two organic materials next to each other. As shown in FIG. 8B, the shape of the cross-section of the distribution pipes allows for placing nozzles of neighboring distribution pipes close to each other. According to some embodiments, which can be combined with other embodiments described herein, a first nozzle of the first distribution pipe and a second nozzle of the second distribution pipe can have a distance of 30 mm or below, such as from 5 mm to 25 mm. More specifically, the distance of the first outlet or nozzle to a second outlet or nozzle can be 10 mm or below. According to some embodiments, three distribution pipes may be provided next to each other.

In view of the above, it is to be understood that the embodiments of the material deposition source arrangement and the embodiments of the vacuum deposition system herein are in particular beneficial for the deposition of organic materials, e.g. for OLED display manufacturing on large area substrates.

With exemplary reference to the flow chart in FIG. 9, embodiments of a method 400 for depositing material on a substrate 170 in a vacuum deposition chamber 310 are described. In particular, the method 400 includes evaporating 410 a material to be deposited in a crucible. For instance, the material to be deposited may be an organic material for forming an OLED device. The crucible may be heated depending on the evaporation temperature of the material. In some examples, the material is heated up to 600° C., such as heated up to a temperature between about 100° C. and 600° C. According to some embodiments, the crucible stands in fluid communication with a distribution pipe.

Further, the method 400 includes providing 420 the evaporated material to a distribution assembly being in fluid communication with the crucible. In some embodiments, the distribution pipe is at a first pressure level, wherein the first pressure level may for instance be typically between about 10⁻² mbar to 10⁻⁵ mbar, more typically between about 10⁻² mbar and 10⁻³ mbar. According to some embodiments, the vacuum deposition chamber is at a second pressure level, which may for instance be between about 10⁻⁵ to 10⁻⁷ mbar. In some embodiments, the material deposition arrangement is configured to move the evaporated material using only the vapor pressure of the evaporated material in a vacuum, i.e. the evaporated material is driven to the distribution pipe (and/or through the distribution pipe) by the evaporation pressure only (e.g. by the pressure originating from the evaporation of the material). For instance, no further elements (such as fans, pumps, or the like) are used for driving the evaporated material to and through the distribution pipe.

Additionally, the method 400 includes guiding 430 the evaporated material through a nozzle having a nozzle passage extending from a nozzle inlet to a nozzle outlet in a flow direction to the vacuum deposition chamber. Typically, guiding 430 the evaporated material through the nozzle further includes guiding the evaporated material through an outlet section of the nozzle passage having an aperture angle α which continuously increases in the flow direction up to an angle of α≥40°, particularly α≥50°, more particularly α≥60°, relative to the flow direction. In particular, guiding 430 the evaporated material through a nozzle passage may include guiding the evaporated material through a nozzle passage of a nozzle according to embodiments described herein, for instance as described with reference to FIGS. 1 to 4.

Accordingly, in view of the above, the embodiments of the nozzle, the embodiments of material deposition source arrangement, the embodiments of the vacuum deposition system, and the embodiments of the method for depositing a material on a substrate, provide for improved high resolution, particularly ultra-high resolution, display manufacturing, e.g. OLED-displays. Particularly, embodiments described herein provide for a homogeneous flow profile over a large distance from the nozzle outlet such that a shadowing effect due to a mask, e.g. a pixel mask, provided in front of a substrate to be coated can be reduced.

This written description uses examples to disclose the disclosure, including the best mode, and also to enable any person skilled in the art to practice the described subject-matter, including making and using any devices or systems and performing any incorporated methods. While various specific embodiments have been disclosed in the foregoing, mutually non-exclusive features of the embodiments described above may be combined with each other. The patentable scope is defined by the claims, and other examples are intended to be within the scope of the claims if the claims have structural elements that do not differ from the literal language of the claims, or if the claims include equivalent structural elements with insubstantial differences from the literal language of the claims.

1-15. (canceled)

16. A nozzle for an evaporated material distribution assembly comprising:
a nozzle inlet for receiving the evaporated material;
a nozzle outlet for releasing the evaporated material; and
a nozzle passage extending between the nozzle inlet and the nozzle outlet and comprising an outlet section having an aperture angle (α) which continuously increases up to the nozzle outlet in the direction from the nozzle inlet to the nozzle outlet.

17. The nozzle according to claim 16, wherein the aperture angle (α) continuously increases up to an angle of α≥40°.

18. The nozzle according to claim 16, wherein the aperture angle (α) continuously increases from an angle of α=0° up to an angle of α=90°.

19. The nozzle according to claim 16, wherein the aperture angle (α) continuously increases such that a diameter of the outlet section of the nozzle passage increases in an exponential manner.

20. The nozzle according to claim 16, wherein the aperture angle (α) continuously increases in the flow direction such that a diameter of the outlet section of the nozzle passage increases in a circular-segment-like manner.

21. The nozzle according to claim 16, wherein the aperture angle (α) continuously increases such that a diameter of the outlet section of the nozzle passage increases in a parabola-like manner.

22. The nozzle according to claim 16, wherein the nozzle comprises a material adapted for an evaporated organic material having a temperature between about 100° C. and about 600° C.

23. The nozzle according to claim 16, wherein the nozzle is configured for a mass flow of less than 0.1 sccm.

24. The nozzle according to claim 16, wherein the nozzle passage has a minimum dimension of less than 8 mm.

25. The nozzle according to claim 16, wherein the outlet section has a length L2 between 2 mm and 20 mm.

26. Use of a nozzle for depositing a material on a substrate in a vacuum deposition chamber, wherein the nozzle is attached to an evaporated material distribution assembly having:
a nozzle inlet for receiving the evaporated material;
a nozzle outlet for releasing the evaporated material; and
a nozzle passage extending between the nozzle inlet and the nozzle outlet and having an outlet section having an aperture angle (α) which continuously increases up to the nozzle outlet in the direction from the nozzle inlet to the nozzle outlet.

27. Use of a nozzle for producing an organic light emitting diode, wherein the nozzle is attached to an evaporated material distribution assembly having:
a nozzle inlet for receiving the evaporated material;
a nozzle outlet for releasing the evaporated material; and
a nozzle passage extending between the nozzle inlet and the nozzle outlet and having an outlet section having an aperture angle (α) which continuously increases up to the nozzle outlet in the direction from the nozzle inlet to the nozzle outlet.

28. A material deposition source arrangement for depositing a material on a substrate in a vacuum deposition chamber, comprising:
an evaporated material distribution assembly in fluid communication with a material source; and
at least one nozzle for the evaporated material distribution assembly, having:
a nozzle inlet for receiving the evaporated material;
a nozzle outlet for releasing the evaporated material; and
a nozzle passage extending between the nozzle inlet and the nozzle outlet and comprising an outlet section having an aperture angle (α) which continuously increases up to the nozzle outlet in the direction from the nozzle inlet to the nozzle outlet.

29. The material deposition source arrangement according to claim 28, wherein the material source is a crucible for evaporating material and wherein the distribution assembly includes a linear distribution pipe.

30. The material deposition source arrangement according to claim 29, wherein the at least one nozzle is in fluid communication with the linear distribution pipe.

31. A vacuum deposition system, comprising:
a vacuum deposition chamber;
a material deposition source arrangement for depositing a material on a substrate in a vacuum deposition chamber, comprising:
a distribution assembly in fluid communication with a material source; and
at least one nozzle for an evaporated material distribution assembly, having:
a nozzle inlet for receiving the evaporated material;
a nozzle outlet for releasing the evaporated material; and
a nozzle passage extending between the nozzle inlet and the nozzle outlet and comprising an outlet section having an aperture angle (α) which continuously increases up to the nozzle outlet in the direction from the nozzle inlet to the nozzle outlet in the vacuum deposition chamber; and
a substrate support for supporting the substrate during deposition.

32. The vacuum deposition system according to claim 31, wherein the vacuum deposition system further comprises a pixel mask between the substrate support and the material source arrangement.

33. The vacuum deposition system according to claim 32, wherein the vacuum deposition system is adapted for simultaneously housing two substrates to be coated on two substrate supports within the vacuum deposition chamber, wherein the material deposition source arrangement is arranged movably between the two substrate supports within the vacuum deposition chamber, the material source of the material deposition source arrangement being a crucible for evaporating organic material, and wherein the pixel mask comprises openings of less than 50 μm.

34. The vacuum deposition system of claim 33, wherein the crucible is in fluid communication with a distribution pipe, and the distribution pipe is in fluid communication with the at least one nozzle.

35. A method for depositing a material on a substrate in a vacuum deposition chamber, comprising:
evaporating a material to be deposited in a crucible;
providing the evaporated material to a distribution assembly being in fluid communication with the crucible; and
guiding the evaporated material through a nozzle having a nozzle passage extending from a nozzle inlet to a nozzle outlet to the vacuum deposition chamber, wherein the guiding the evaporated material through the nozzle comprises guiding the evaporated material through an outlet section of the nozzle passage having an aperture angle (α) which continuously increases up to the nozzle outlet in the direction from the nozzle inlet to the nozzle outlet up to angle of α≥40°.
